(19) United States
(12) Patent Application Publication
(10) Pub. No.: US 2005/0263070 A1
(43) Pub. Date: Dec. 1, 2005

(54) Pressure control and plasma confinement in a plasma processing chamber

(75) Inventor: Steven T. Fink, Mesa, AZ (US)

Correspondence Address: PILLSBURY WINTHROP SHAW PITTMAN, LLP, P.O. BOX 10500, MCLEAN, VA, 22102, US

(73) Assignee: Tokyo Electron Limited, Tokyo (JP)

(21) Appl. No.: 10/852,450

(22) Filed: May 25, 2004

(51) Int. Cl. H05H 1/24; C23C 16/00

(52) U.S. Cl. 118/715; 427/569

(57) ABSTRACT

A plasma apparatus which includes a vacuum chamber provided with an exhaust port and a chuck assembly disposed inside the vacuum chamber. The plasma apparatus also includes a plasma confinement and pressure control apparatus disposed proximate to the substrate. The plasma confinement and pressure control apparatus includes a plurality of ring members disposed adjacent to each other in a superposed fashion and a plurality of lift assemblies disposed along a circumference of the plurality of ring members. The plurality of lift assemblies are arranged to support the plurality of ring members. The plasma confinement apparatus further includes at least one lift mechanism connected to the lift assemblies. The lift mechanism is configured to translate at least one of the plurality of ring members relative to a reference plane and to tilt at least one of the plurality of the ring members relative to the reference plane.

### FIELD OF THE INVENTION

The present invention pertains to plasma processing systems and in particular to an apparatus and a method for controlling confinement of a plasma and an apparatus and a method to provide pressure control in a plasma processing chamber.

### BACKGROUND OF THE INVENTION

Plasma processing systems are used in the manufacture and processing of semiconductors, integrated circuits, displays and other devices and materials, to remove material from or to deposit material on a substrate such as a semiconductor substrate. In some instances, these plasma processing systems use electrodes for providing RF energy to a plasma useful for depositing on or removing material from a substrate.

There are several different kinds of plasma processes used during wafer or substrate processing. These processes include, for example: plasma etching, plasma deposition, plasma assisted photoresist stripping and in-situ plasma chamber cleaning.

Plasma processing systems often operate with a blend of gasses which must flow through a processing chamber. A pumping system is employed to remove gasses from the processing system. A chuck assembly is used to hold the substrate to be processed. Due to the presence of the chuck assembly, the symmetry of the pumping system relative to the substrate is sometimes sacrificed. The pumping system is sometimes positioned to access the processing chamber from the side rather than from the bottom or top of the chamber. The pumping system is thus rendered asymmetric. In this asymmetric design pressure gradients may occur across the substrate being processed.

### BRIEF SUMMARY OF THE INVENTION

An aspect of the present invention is to provide a plasma confinement and pressure control apparatus. The confinement apparatus includes a plurality of ring members disposed adjacent to each other in a superposed fashion. The confinement apparatus also includes a plurality of lift assemblies disposed along a circumference of the plurality of ring members. The plurality of lift assemblies are arranged to support the plurality of ring members. The confinement apparatus further includes at least one lift mechanism connected to the plurality of lift assemblies. The lift mechanism is configured to translate at least one of the plurality of ring members relative to a reference plane and to tilt at least one of the plurality of the ring members relative to the reference plane.

Another aspect of the present invention is to provide a plasma apparatus. The plasma apparatus includes a vacuum chamber provided with an exhaust port and a chuck assembly disposed inside the vacuum chamber. The chuck assembly is constructed and arranged to hold a substrate. The plasma apparatus also includes a plasma confinement and pressure control apparatus disposed proximate to the substrate. The plasma confinement and pressure control apparatus includes a plurality of ring members disposed adjacent to each other in a superposed fashion and a plurality of lift assemblies disposed along a circumference of the plurality of ring members. The plurality of lift assemblies are arranged to support the plurality of ring members. The plasma confinement apparatus further includes at least one lift mechanism connected to the lift assemblies. The lift mechanism is configured to translate at least one of the plurality of ring members relative to a reference plane and to tilt at least one of the plurality of the ring members relative to the reference plane.

Another aspect of the invention is to provide a method of controlling pressure in a vicinity of a substrate or wafer disposed on a chuck assembly in a plasma apparatus with a structure including a plurality of rings disposed adjacent to each other and a plurality of lift assemblies disposed along a circumference of the plurality of ring members to support the plurality of ring members. The method includes controlling a spacing between at least two of the plurality of ring members and adjusting a pressure inside a volume delimited by the plurality of ring members across the substrate by controlling a tilting of at least one of the plurality of ring members relative to another one of the ring members.

Another aspect of the invention is to provide a method of controlling a plasma in a vicinity of a substrate disposed on a chuck assembly in a plasma apparatus with a structure including a plurality of rings disposed adjacent to each other and a plurality of lift assemblies disposed along a circumference of the plurality of ring members to support the plurality of ring members. The method includes applying at least one of an electrical field and a magnetic field to a plasma volume delimited by the plurality of the ring members by connecting at least one of the plurality of ring members to an electrical potential or by disposing magnetic components in a periphery of at least one of the ring members and altering characteristics of the plasma in the vicinity of the substrate.

### BRIEF DESCRIPTION OF THE DRAWINGS

In the accompanying drawings:

FIG. 1 is a schematic of plasma reactor having a confinement ring structure according to an embodiment of the present invention;

FIG. 2 is a cut-away top view of the plasma reactor of FIG. 1;

FIG. 3 is a transverse elevational view of a plasma reactor with cut-away views of lift assemblies according to an embodiment of the present invention.

FIG. 4 is an enlargement of an area of the plasma reactor of FIG. 3 showing some details of the confinement ring structure and the lift assemblies;

FIG. 5 is an expanded view of a confinement ring structure according to an embodiment of the present invention;

FIG. 6 is a cut-away view of an area of a plasma reactor showing the confinement ring structure and lift assemblies according to an embodiment of the present invention;

FIG. 7 is a cross-sectional detail of a lift assembly according to an embodiment of the present invention;

FIG. 8 is a transverse elevational view of a plasma reactor with an alternative configuration of lift assemblies according to another embodiment of the present invention;

FIG. 9 is a transverse elevational view of a plasma reactor with yet an another configuration of lift assemblies according to another embodiment of the present invention;

FIG. 10 is a cross-sectional detail of a lift assembly according to another embodiment of the present invention; and

FIG. 11 is a cut-away view of an area of a plasma reactor showing portions of a confinement ring having a plasma-monitoring device according to an embodiment of the present invention.

### DETAILED DESCRIPTION OF SEVERAL EMBODIMENTS OF THE INVENTION

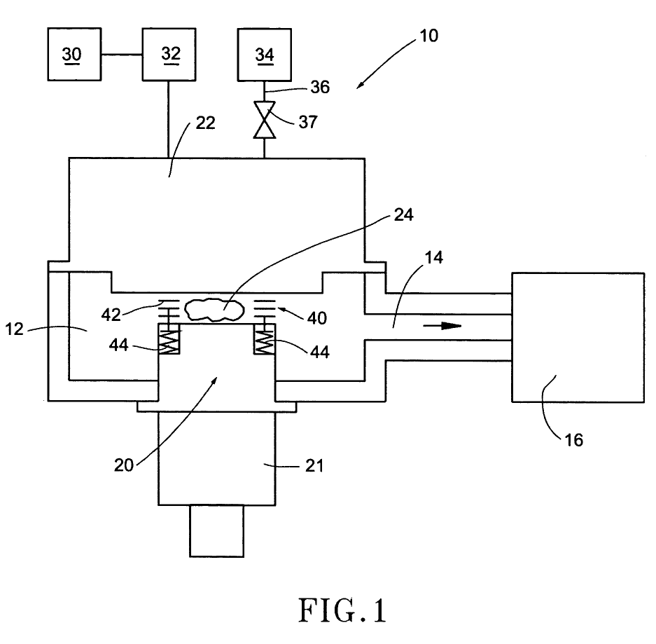

FIG. 1 shows an embodiment of a plasma reactor according to the present invention. The plasma reactor 10 includes a plasma chamber 12 that functions as a vacuum processing chamber adapted to perform plasma etching from and/or material deposition on a workpiece (not shown). The workpiece can be, for example, a semiconductor wafer such as a silicon wafer. However, other types of substrates are also within the scope of the present invention. The chamber 12 is provided with an exhaust port 14 for connecting a vacuum pump 16. Vacuum pump 16 can be, for example, a turbo-molecular pump (TMP) configured to evacuate excess process gases from the chamber 12.

The plasma reactor 10 also includes a chuck assembly 20 and an electrode assembly 22. The chuck assembly 20 supports the workpiece while it is processed in the chamber 12. In this embodiment, the electrode assembly 22 is electrically coupled to the plasma when the workpiece is being plasma processed. For example, a capacitively coupled plasma (CCP) source assembly including a plate electrode can be used in the plasma reactor 10. Alternatively, an inductively coupled plasma (ICP) source assembly including a coil can be used in the plasma reactor 10 or a combination of a CCP source and an ICP source can also be used in the plasma reactor 10. Other plasma source assemblies such as helicon wave source, surface wave source, electron cyclotron resonance (ECR) source, or slotted plane antenna (SPA) source can also be used in the plasma reactor 10. The plasma is formed in an interior region 24. The plasma may have a plasma density (i.e., number of ions/volume, along with energy/ion) that is uniform, unless the density needs to be tailored to account for other sources of process non-uniformities or to achieve a desired process non-uniformity. In order to protect the electrode assembly 22 and other components from heat damage due to the plasma, a cooling system, not shown, in fluid communication with the electrode assembly 22 is preferably included for cooling the electrode assembly 22 by, for example, flowing a cooling fluid to and from the electrode assembly 22.

The electrode assembly 22 may be electrically connected to an RF power supply system 30 via an impedance match network 32. The impedance match network 32 matches the output impedance of RF power supply system 30 to the input impedance of the electrode assembly 22 and the associated excited plasma. In this way, the power may be delivered by the RF power supply to the plasma electrode assembly 22 and the associated excited plasma with reduced reflection.

In addition, the chuck assembly 20 used to support the workpiece, i.e., the substrate, or wafer, can also be provided with an RF power supply or a DC power supply (not shown) coupled thereto to bias the workpiece. Similarly to the electrode assembly 22, the RF bias can be applied to wafer chuck assembly 20 through an impedance match network 21.

The plasma reactor 10 further includes a gas supply system 34 in pneumatic communication with the plasma chamber 12 via one or more gas conduits 36 for supplying gas in a regulated manner using a regulator 37 to form the plasma. The gas supply system 36 can supply one or more gases such as chlorine, hydrogen-bromide, octafluorocyclobutane, and various other fluorocarbon compounds, and for chemical vapor deposition applications can supply one or more gases such as silane, tungsten-tetrachloride, titanium-tetrachloride, or the like.

The plasma reactor 10 further includes a confinement ring structure 40. The confinement ring structure 40 is constructed and arranged to confine the plasma above the substrate in interior region 24 and also to control the gas pressure distribution above and/or in the vicinity of the substrate.

In the case where the pumping system is positioned on a side wall of the chamber 12, i.e., when the exhaust port 14 is located on a side wall of the chamber 12, as illustrated in FIG. 1, the pumping configuration can be asymmetric relative to the chuck assembly. One effect stemming from an asymmetric vacuum design is the observation of pressure field non-uniformity above the substrate when the chamber is evacuated from the side. A pressure gradient with about 10-20% variation may occur across the substrate being processed. In general, for moderate to high pressures (e.g., P>20 mTorr), a region of low pressure can be observed at an azimuthal location adjacent the exhaust port. As a result of an asymmetric pumping, the plasma process obtained can be also asymmetric. In order to homogenize the pressure in the vicinity of the substrate, across a substrate surface, the confinement ring structure 40 is used to surround the interior region 24.

The confinement ring structure 40 not only provides confinement of the plasma above the substrate but also allows normalization of pressure gradients across the substrate being processed. This can be accomplished by manipulating the geometrical characteristics of the confinement ring structure 40. In this way, the plasma process can be improved. This and other aspects of the confinement ring structure will be explained in more detail in the following paragraphs.

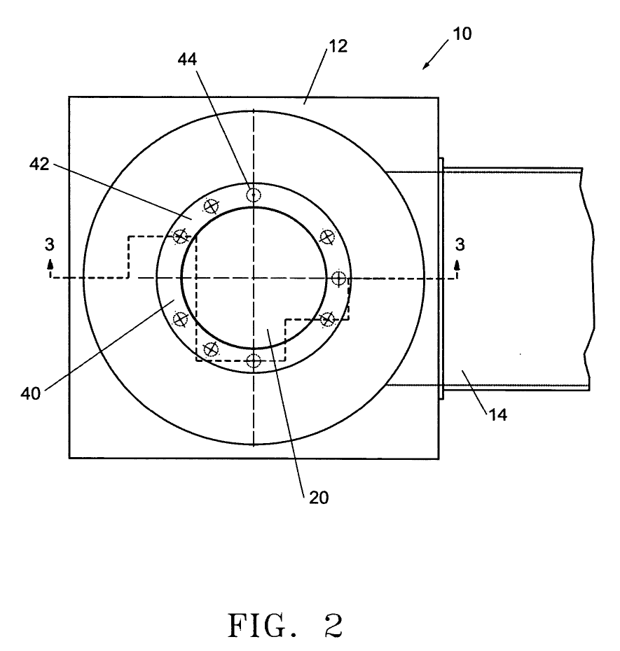

The confinement ring structure 40 includes a plurality of ring members 42 disposed adjacent to each other in a superposed fashion as shown in FIG. 1. The confinement ring structure 40 also includes a plurality of lift assemblies 44 disposed along a circumference or a periphery of the plurality of ring members 42, as shown in more detail in FIG. 2.

FIG. 2 shows a cut-away top view of the plasma reactor 10. The chuck assembly 20 is located inside the plasma chamber 12. The confinement ring structure 40 is also shown, but only the top most ring member of the plurality of ring members 42 can be seen from the top as all the other ring members lie beneath this top most ring member.

FIG. 2 also shows the disposition of the plurality of lift assemblies 44 in the confinement ring structure 40. The plurality of lift assemblies 44 are disposed around the circumference of the ring members 42. The plurality of lift assemblies 44 are arranged to support the plurality of ring members 42. In this exemplary embodiment, each ring member is provided with three individual lift assemblies. In this way each ring member is supported independently from the other ring members. As will be explained further in the following paragraphs, this provides the flexibility of moving one ring member relative to the other ring members independently. Furthermore, because each ring member is provided with three lift assemblies 44, each ring member can be translated in a common centerline with all the ring members and/or tilted relative to a reference plane, such as a plane defined by a surface of the chuck assembly, or tilted relative to a plane defined by another of the ring members.

Although the ring members 42 are illustrated in FIG. 2 having a circular geometry, other geometries, such as but not limited to, polygonal and elliptical geometries, are also within the scope of the present invention. Similarly, although three lift assemblies are used to support and actuate each ring member, it must be appreciated that more than three lift assemblies can be used to actuate one or more of the ring members.

The ring members 42 can be manufactured from metallic materials, nonmetallic materials, ceramic materials, or quartz. Furthermore, the ring members 42 can be bare or coated with various materials depending on plasma process requirements. The ring members can be supplied singly or as part of a consumable process kit.

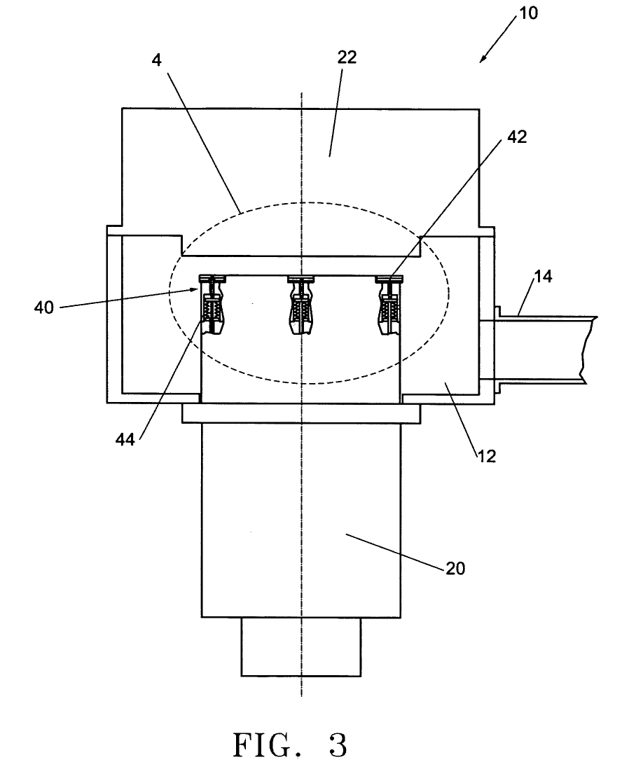

FIG. 3 is a transverse elevational view of the plasma reactor 10 taken at line 3-3 in FIG. 2. FIG. 3 shows an embodiment of the plasma reactor 10 where three lift assemblies 44 used to support one ring member 42 of the confinement ring structure 40 are incorporated into the chuck assembly 20. The lift assemblies 44 are shown mounted on the periphery of the chuck assembly 20. In this embodiment, the lift assemblies 44 can retract such that the ring members are flush with a surface of the chuck assembly supporting the substrate. This facilitates the placement and removal of the substrate before the start of the plasma process or after the end of the plasma process. This also renders the ensemble confinement ring structure 40 and chuck assembly 20 more compact and provides easier handling such as during removal for servicing, cleaning or the like.

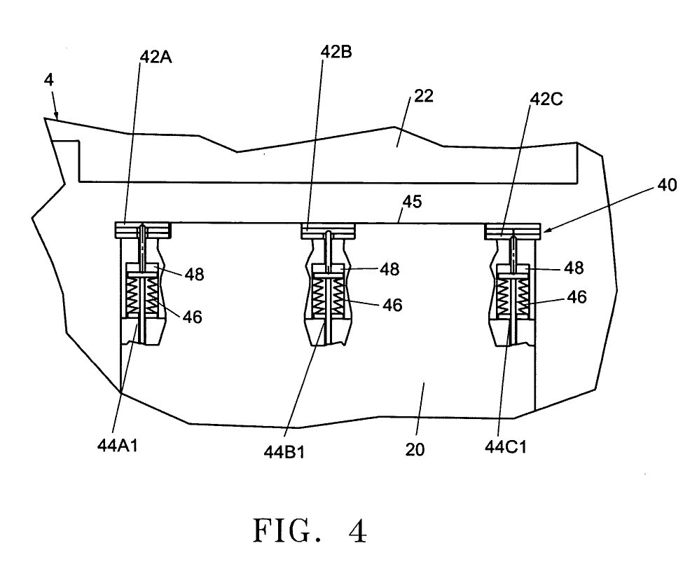

FIG. 4 is an enlargement of area 4 in FIG. 3 between the electrode assembly 22 and the chuck assembly 20. FIG. 4 shows details of the confinement ring structure 40 in relation with the chuck assembly 20 and the electrode assembly 22. As stated previously, the confinement ring structure 40 may employ three lift assemblies for each ring member 42. The three lift assemblies are distributed along a periphery of each ring member 42. In this embodiment, the confinement ring structure 40 has three ring members. Thus, the confinement ring structure 40 comprises a total of nine lift assemblies.

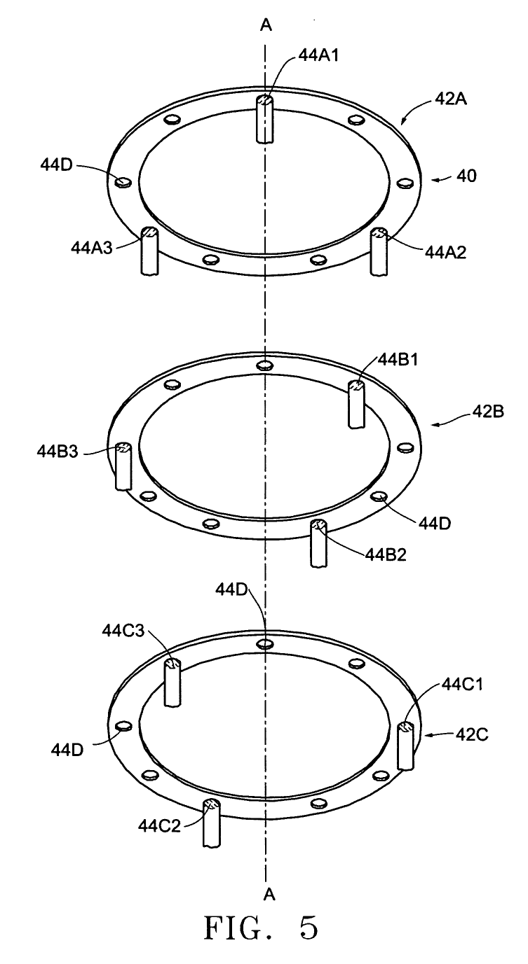

A ring member 42A is supported by lift assemblies 44A1, 44A2 and 44A3. Among lift assemblies 44A1, 44A2 and 44A3, only the lift assembly 44A1 is shown in FIG. 4. However, the positioning of the lift assemblies 44A1, 44A2 and 44A3 in ring member 42A relative to each other is illustrated in detail in FIG. 5. FIG. 5 is an expanded view of the ring members 42A, 42B and 42C. Similarly, the ring member 42B is supported by lift assemblies 44B1, 44B2 and 44B3. Among the lift assemblies 44B1, 44B2 and 44B3, only the lift assembly 44B1 is shown in FIG. 4. However, the positioning of the lift assemblies 44B1, 44B2 and 44B3 relative to each other in ring member 42B is illustrated in detail in FIG. 5. Similarly, the ring member 42C is supported by lift assemblies 44C1, 44C2 and 44C3. Among the lift assemblies 44C1, 44C2 and 44C3, only the lift assembly 44C1 is shown in FIG. 4. However, the positioning of the lift assemblies 44C1, 44C2 and 44C3 relative to each other in the ring member 42C is illustrated in detail in FIG. 5.

The lift assemblies include lift pins that can extend and retract to lift and lower, respectively, individually each of the ring members 42A, 42B and 42C at three different points (the supporting points). The areas of contact or interface between the lift assemblies 44A1, 44A2 and 44A3 and the ring member 42A are shown as cross-hatched areas in FIG. 5. Similarly, the areas of contact or interface between the lift assemblies 44B1, 44B2 and 44B3 and the ring member 42B as well as the supporting areas of contact or interface between the lift assemblies 44C1, 44C2 and 44C3 and the ring member 42C are also shown as cross-hatched areas in FIG. 5. The circular features 44D in each ring member represent a hole through which, for example, corresponding lift pins can extend to reach a corresponding ring member. For example, the top most ring member 42A is supported by the lift assemblies 44A1, 44A2 and 44A3 and in order to reach the top most ring member 42A, the lift assemblies 44A1, 44A2 and 44A3 go through holes 44D in each of the other two ring members 42B and 42C.

Each one of the lift assemblies can be connected to a lift mechanism. For example, each one of the lift assemblies 44A1, 44A2 and 44A3 can be connected to separate lift mechanisms or to a same lift mechanism having three independent actuation systems to provide independent control of each one of the lift assemblies 44A1, 44A2 and 44A3. Similarly, each one of the lift assemblies 44B1, 44B2 and 44B3 can be connected to separate lift mechanisms or to a same lift mechanism having three independent actuation systems to provide independent control of each one of the lift assemblies 44B1, 44B2 and 44B3. In the same manner, each one of the lift assemblies 44C1, 44C2 and 44C3 can be connected to separate lift mechanisms or to a same lift mechanism having three independent actuation systems to provide independent control of each one of the lift assemblies 44C1, 44C2 and 44C3. Suitable lift mechanisms can be any one of a gear driven lift mechanism, a belt driven lift mechanism, a pneumatic or hydraulic lift mechanism, a piezo-electric or a stepper motor lift mechanism.

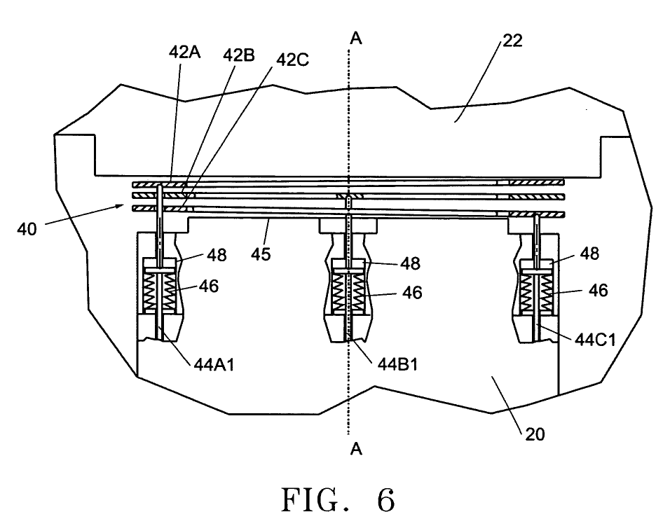

The lift mechanisms may be operated to move or translate anyone of the ring members 42A, 42B and 42C relative to a fixed reference, for example a plane 45 (shown in FIG. 6) defined by the chuck assembly 20, along a common centerline or axis AA (shown in FIG. 5) of the ring members 42A, 42B and 42C. The lift mechanisms may also be controlled to move or translate one ring member, for example the ring member 42A, relative to another one of the ring members, for example ring member 42B, along the common centerline AA of the ring members 42A, 42B and 42C.

In addition, the lift mechanisms may also be operated to tilt at least one of the ring members 42A, 42B and 42C relative to plane defined by another one of the ring members 42A, 42B and 42C or relative to a plane defined by the chuck 20. For example, the lift mechanism(s) can be operated to tilt the ring member 42A relative to a plane defined by the ring member 42B or vice-versa. Furthermore, the lift mechanism(s) can be operated to translate anyone of the ring members relative to another one of the ring members while the latter ring member is tilted. Although, only few examples of relative movement of the ring members are described above, it must be appreciated that any combination of translation and tilting of the ring members is within the scope of the present invention.

For example, as shown in FIG. 6, the ring members 42A, 42B and 42C are shown moved axially extended along the common centerline or axis AA away from plane 45 of the chuck assembly 20 and are shown spaced apart from each other. In addition to being translated in the direction of the common axis AA, the ring members 42A and 42C are tilted relative to the plane 45 of the chuck assembly 20 while the ring member 42B is parallel with to the plane 45 of the chuck assembly 20. Consequently, the ring members 42A and 42C are tilted relative to a plane defined by the ring member 42B. In this instance, the ring members 42A and 42C are tilted in different directions. The ring member 42A is tilted upwardly towards the electrode assembly 22 while the ring member 42C is tilted downwardly towards the chuck assembly 20.

By controlling the spacing between the ring members and controlling the tilting of the ring members relative to each other or relative to a plane of the chuck assembly, it is possible to control the flow conductance of gases used in a plasma process and thus the overall pressure gradient distribution above and/or across the wafer can be controlled. For example, the ring assemblies may be tilted more or less to alter the pumping flow of gas in specific areas above the chuck in order to normalize pressure gradients across the wafer. Furthermore, the ring members may be moved or controlled dynamically during a plasma process, for example, to alter the pressure gradient at specific periods of time during plasma processing of the wafer.

Therefore, an aspect of the present invention is also to provide a method of controlling pressure in a vicinity of a substrate or wafer disposed on a chuck assembly in a plasma apparatus with a structure including a plurality of rings disposed adjacent to each other and a plurality of lift assemblies disposed along a circumference of the plurality of ring members to support the plurality of ring members. The method includes controlling a spacing between at least two of the plurality of ring members and adjusting a pressure inside a volume delimited by the plurality of ring members across the substrate by controlling a tilting of at least one of the plurality of ring members relative to another one of the ring members.

In addition to lift pins, the lift assemblies also include bellows 46. Bellows 46 allow maintenance of the integrity of the vacuum inside the process chamber 12 by isolating the inside of the chamber from the lift assembly, which can be at atmospheric pressure.

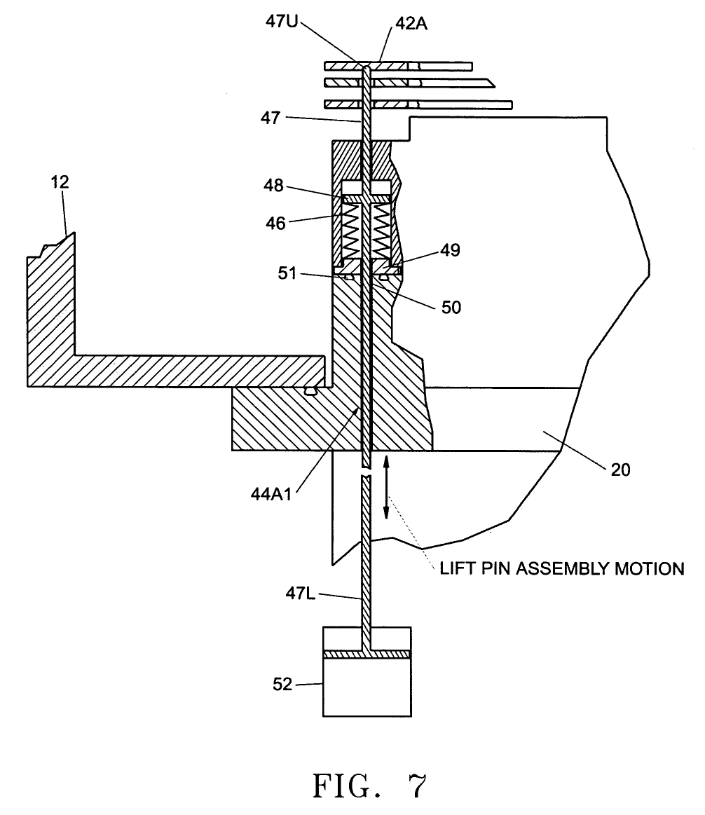

FIG. 7 shows in more detail the disposition of the lift pin and the bellows in one lift assembly. Each bellows 46 is terminated at one end with a ring element 48 such that the ring element 48 and the lift pin 47, for example of lift assembly 44A1, together form an integrated assembly. When the lift pin 47 moves or translates, the bellows 46 attached to the ring element 48 extends with the movement of the lift pin 47. Each bellows 46 is also terminated at the opposite end with a ring element 49. The ring element 49 has a hole 50 through which the lift pin 47 slides. The ring element 49 is attached to a portion of the chuck assembly 20 and seals 51 are used to seal the interface between the ring element 49 and a surface of the chuck assembly 20. The upper end portion 47U of the lift pin 47 supports a ring member, for example to ring member 42A. The lower end portion 47L of the lift pin 47 is connected to a lift mechanism 52.

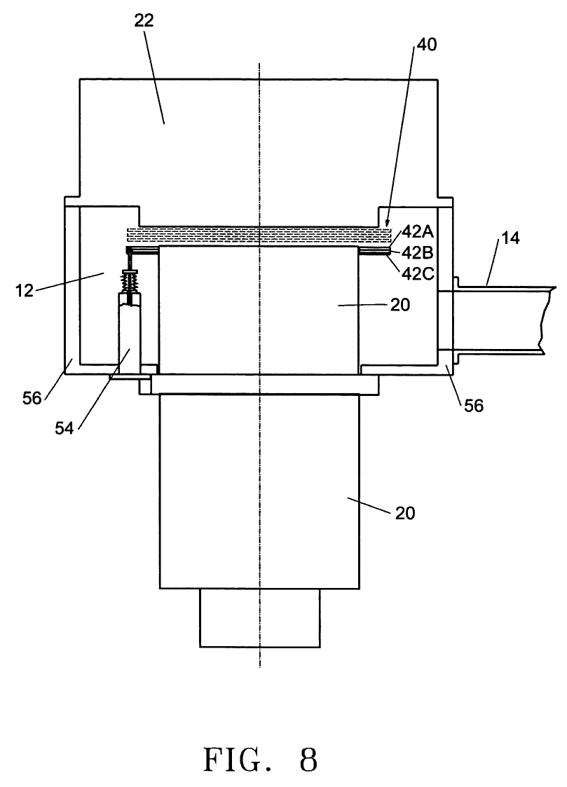

The lift assemblies can be mounted on or within the chuck assembly 20 as shown, for example in FIG. 4, but can also be mounted on another structure such as a wall of the process chamber 12. For example, lift assemblies 54 can be mounted to the floor 56 of the process chamber 12 as shown in FIG. 8. In this way, for example, the ring members 42A, 42B and 42C of confinement ring structure 40 can be moved independently of the chuck assembly 20.

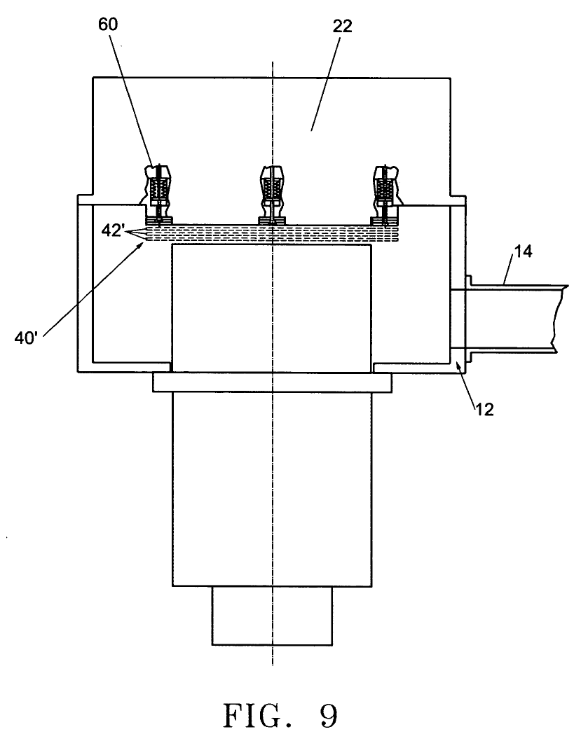

Alternatively, the lift assemblies can be mounted to the electrode assembly 22 as shown in FIG. 9. In this embodiment, the confinement ring structure 40′ is held by a plurality of lift assemblies 60 which are connected at one end to the electrode assembly 22. Similarly to the previous embodiments, the confinement ring structure 40′ comprises a plurality of ring members 42′ disposed adjacent to each other in a superposed fashion. The plurality of lift assemblies 60 are disposed along a circumference or a periphery of the plurality of ring members 42′.

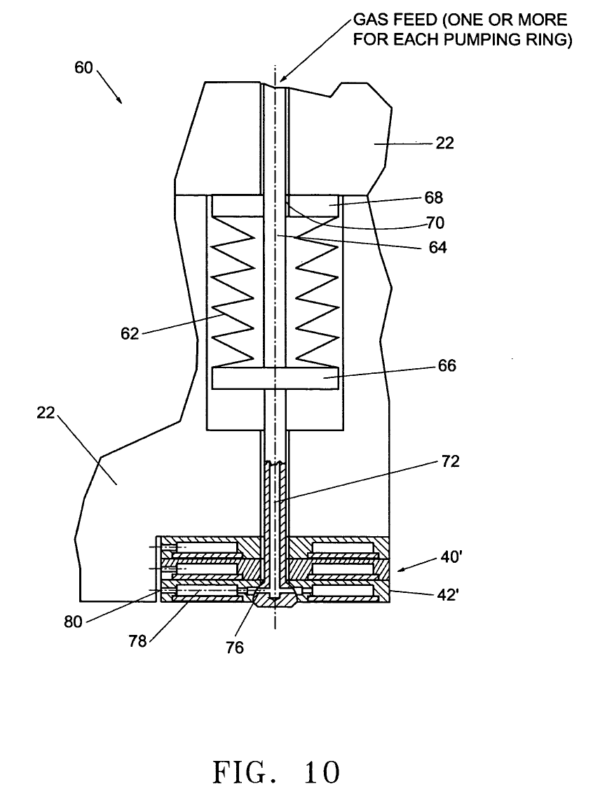

FIG. 10 shows a cross-sectional detail of the lift assembly 60. Lift assembly 60 includes bellows 62 connected to lift pin 64 via a ring member 66. Bellows 62 is terminated at one end with the ring member 66 and at an opposite end with a ring member 68. In this way, the lift pin 64 forms an integrated assembly with the ring member 66. When the lift pin 64 moves, the bellows 62 being attached to the ring member 66 extends or retracts with the movement of the lift pin 64. The ring member 68 has a hole 70 through which the lift pin 64 slides. The ring 68 is attached to a portion of the electrode assembly 22. An upper portion of the lift pin 64 is connected to a lift mechanism (not shown) while a lower portion of the lift pin 64 is connected to a ring member 42′ of the confinement ring structure 40.

The lift pin 64 can be made hollow and can be used to deliver gas into the plasma processing volume in the vicinity of the substrate. In other words, the lift pin 64 is configured to include a gas feed canal 72 for injecting gas into the plasma processing volume. In this instance, each ring member 42′ can be configured to transfer gas from the hollow lift pin 64 into the plasma processing volume. For example, gas can be fed through one or more hollow lift pins 64, through a number of gas plenum inject holes 76, to a gas plenum 78 within the confinement ring member 42′ and the gas plenum is injected to the process volume through a number of gas inject holes 80.

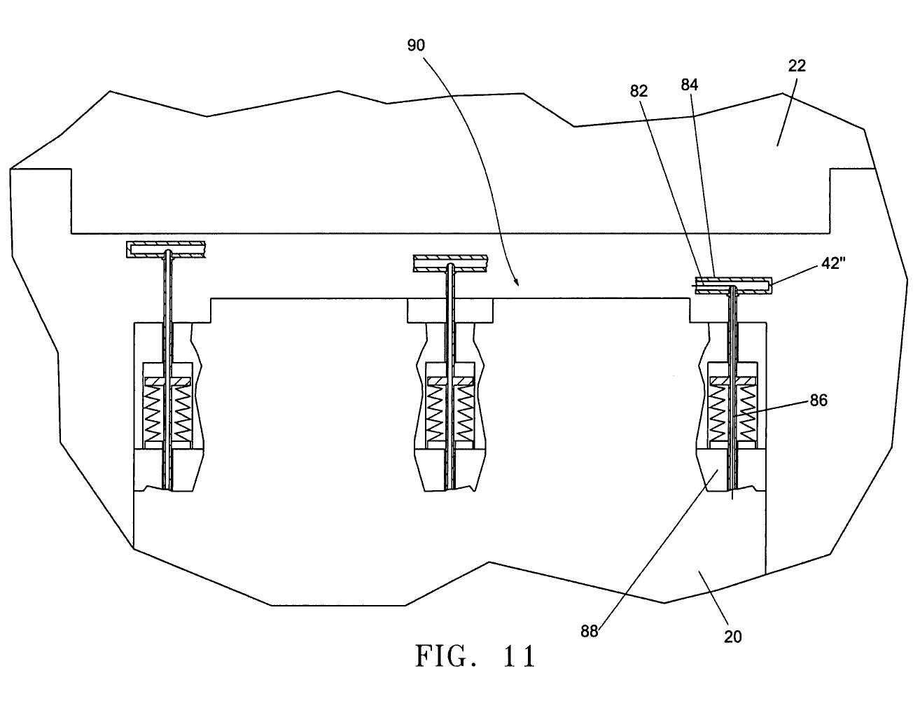

Similarly, instead of using the lift assemblies and confinement ring members to deliver gas into the plasma processing volume in the vicinity of the substrate, the confinement ring member 42″ may be configured to carry plasma monitoring devices 82 as shown in FIG. 11. For example, the plasma monitoring device(s) 82 may be positioned inside a cavity 84 of the confinement ring member 42″. Electrical access to the monitoring device 82 inside the confinement ring member 42″ can be accomplished through a canal in the lift pin 86 of the lift assembly 88. By inserting plasma-monitoring devices in the confinement rings, it is possible to measure parameters of the plasma in the vicinity of the plasma. This allows measurements of plasma parameters “in-situ.” As a result, more accurate measurements of the plasma parameters can be obtained.

When the internal cavity 84 of the confinement ring member 42″ and the interface between the lift pin 86 and the confinement ring member 42″ are sealed from the plasma processing volume 90, the plasma monitoring device 82 is at atmospheric pressure. This allows, for example, to have a direct electrical access from external electronic devices to the plasma monitoring device 82 via the canal in the lift pin 86 by using electrical wires.

When the internal cavity 84 and the interface between the lift pin 86 and the confinement ring member 42″ are not completely sealed from the plasma processing volume 90, the plasma monitoring device 82 may be under a vacuum pressure as the plasma processing volume is also under a certain vacuum pressure. In this case, in order to provide electrical connections to the plasma monitoring devices while maintaining the integrity of the vacuum, electrical feed-through in the lift pin 86 may be necessary. Examples of plasma monitoring devices include, but are not limited to, temperature measurement devices such as a temperature probe, RF voltage measurement devices, DC voltage measurement devices, optical devices via optical fibers, and electrical current measurement devices or a combination thereof.

In addition, magnetic components can also be positioned inside cavities in the confinement ring members to create a magnetic field around the plasma volume to further alter the characteristics of the plasma. The magnetic components can be any one of permanent magnets, solenoid-type magnets or a combination thereof. Furthermore, the confinement ring members can also be electrically polarized by applying electrical potentials to the different confinement ring members. This is accomplished, for example, by running electrical wires through canals inside the lift pins. In this way an electrical field is generated around the plasma and as a result it is possible to alter the plasma characteristics to achieve the desired effects on a workpiece. Moreover, two adjacent ring members can be electrically isolated from each other to create a voltage potential difference between adjacent ring members. This allows further flexibility in controlling the plasma.

Therefore, an aspect of the present invention is also to provide a method of controlling a plasma in a vicinity of a substrate disposed on a chuck assembly in a plasma apparatus with a structure including a plurality of rings disposed adjacent to each other and a plurality of lift assemblies disposed along a circumference of the plurality of ring members to support the plurality of ring members. The method includes applying at least one of an electrical field and a magnetic field to a plasma volume delimited by the plurality of the ring members by connecting at least one of the plurality of ring members to an electrical potential or by disposing magnetic components in a periphery of at least one of the ring members and altering characteristics of the plasma in the vicinity of the substrate.

Although the confinement ring structure has been shown having a circular shape, it should be appreciated that a different shape such as a polygonal or elliptical shape is also within the scope of the present invention. The many features and advantages of the present invention are apparent from the detailed specification and thus, it is intended by the appended claims to cover all such features and advantages of the described apparatus which follow the true spirit and scope of the invention.

Furthermore, since numerous modifications and changes will readily occur to those of skill in the art, it is not desired to limit the invention to the exact construction and operation described herein. Moreover, the process and apparatus of the present invention, like related apparatus and processes used in the semiconductor arts tend to be complex in nature and are often best practiced by empirically determining the appropriate values of the operating parameters or by conducting computer simulations to arrive at a best design for a given application. Accordingly, all suitable modifications and equivalents should be considered as falling within the spirit and scope of the invention.

1. A plasma confinement and pressure control apparatus, comprising:
a plurality of ring members disposed adjacent to each other in a superposed fashion;
a plurality of lift assemblies disposed along a circumference of the plurality of ring members, the plurality of lift assemblies arranged to support the plurality of ring members; and
at least one lift mechanism connected to each of the plurality of lift assemblies,
wherein the at least one lift mechanism is configured to translate at least one of the plurality of ring members relative to a reference plane and to tilt the at least one of the plurality of the ring members relative to the reference plane.

2. A plasma confinement and pressure control apparatus as in claim 1, wherein the reference plane is one of a fixed reference plane or a plane defined by one of the plurality of ring members.

3. A plasma confinement and pressure control apparatus as in claim 1, wherein the plurality of ring members each have a circular shape, a polygonal shape, an elliptical shape or a combination thereof.

4. A plasma confinement and pressure control apparatus as in claim 1, wherein the at least one lift mechanism has a plurality of independent actuation systems connected to the plurality of lift assemblies.

5. A plasma confinement and pressure control apparatus as in claim 1, further comprising a support structure, wherein the plurality of lift assemblies are mounted to the support structure.

6. A plasma confinement and pressure control apparatus as in claim 5, wherein the plurality of lift assemblies are retractable such that one of the plurality of ring members is flush with a surface of the support structure.

7. A plasma confinement and pressure control apparatus as in claim 1, wherein the plurality of lift assemblies comprise a plurality of lift pins, each lift pin is connected at one end to one of the plurality of ring members and connected at another end to the lift mechanism.

8. A plasma confinement and pressure control apparatus as in claim 7, wherein the at least one lift mechanism is configured to extend or retract independently the plurality of lift pins to lift, lower or tilt at least one of the ring members.

9. A plasma confinement and pressure control apparatus as in claim 8, wherein the at least one lift mechanism is configured to control a spacing between at least two of the plurality of ring members.

10. A plasma confinement and pressure control apparatus as in claim 9, wherein the spacing between at least two of the plurality of ring members is controllable to adjust a pressure inside a volume defined by the plurality of ring members.

11. A plasma confinement and pressure control apparatus as in claim 8, wherein the at least one lift mechanism is configured to control a tilting of at least one of the plurality of ring members relative to another of the plurality of ring members.

12. A plasma confinement and pressure control apparatus as in claim 11, wherein the tilting between at least two of the plurality of ring members is controllable to adjust a pressure inside a volume defined by the plurality of ring members.

13. A plasma confinement and pressure control apparatus as in claim 7, wherein the plurality of lift assemblies further comprise a plurality of bellows, each bellows is terminated at one end with a first ring element connected to the lift pin and terminated at an another end with a second ring element having a hole through which the lift pin slides.

14. A plasma confinement and pressure control apparatus as in claim 13, wherein the bellows is configured to isolate pressure environments inside the bellows and outside the bellows.

15. A plasma confinement and pressure control apparatus as in claim 1, wherein the at least one lift mechanism is a gear driven lift mechanism, a belt driven lift mechanism, a pneumatic lift mechanism, a hydraulic lift mechanism, a piezo-electric lift mechanism or a stepper motor lift mechanism.

16. A plasma confinement and pressure control apparatus as in claim 1, wherein the plurality of lift assemblies comprise a plurality of lift pins, at least one of the lift pins having a canal configured to transfer gas into a gas plenum within at least one of the plurality of ring members.

17. A plasma confinement and pressure control apparatus as in claim 16, wherein the at least one of the plurality of ring members has a plurality of holes through which gas is injected into a volume defined by the plurality of ring members.

18. A plasma confinement and pressure control apparatus as in claim 1, further comprising a plasma-monitoring device disposed within a cavity in at least one of the plurality of ring members, wherein the plurality of lift assemblies comprise a plurality of lift pins connected to the plurality of ring members and at least one of the plurality of lift pins has a canal configured to electrically access the plasma-monitoring device disposed within the cavity in the at least one of the plurality of ring members.

19. A plasma confinement and pressure control apparatus as in claim 18, wherein the plasma-monitoring device includes any one of a temperature measuring device, a radio-frequency measuring device, a DC voltage measuring device, an electrical current measuring device or a combination thereof.

20. A plasma confinement and pressure control apparatus as in claim 18, wherein the plasma-monitoring device is configured to measure a parameter of a plasma in a volume enclosed by the plurality of ring members.

21. A plasma confinement and pressure control apparatus as in claim 1, further comprising a magnetic component disposed within a cavity in at least one of the plurality of ring members.

22. A plasma confinement and pressure control apparatus as in claim 21, wherein the magnetic component includes any one of a permanent magnet, a solenoid-type magnet or a combination thereof.

23. A plasma confinement and pressure control apparatus as in claim 21, wherein the magnetic component is configured to generate a magnetic field to confine a plasma in a volume enclosed by the plurality of ring members.

24. A plasma confinement and pressure control apparatus as in claim 1, wherein at least one of the ring members is electrically polarized by applying an electrical potential.

25. A plasma confinement and pressure control apparatus as in claim 24, wherein the plurality of lift assemblies comprise a plurality of lift pins connected to the plurality of ring members and at least one of the plurality of lift pins has a canal therethrough configured to run an electrical connection to at least one of the ring members.

26. A plasma confinement and pressure control apparatus as in claim 24, wherein at least two adjacent ring members are electrically isolated from each other.

27. A plasma confinement and pressure control apparatus as in claim 26, wherein the at least two adjacent ring members are held at different electrical potentials.

28. A plasma confinement and pressure control apparatus as in claim 1, wherein the plurality of ring members are manufactured from at least one of metallic materials, ceramic materials, or quartz.

29. A plasma confinement and pressure control apparatus as in claim 1, wherein the plurality of ring members are coated with various materials depending on plasma process requirements.

30. A plasma confinement and pressure control apparatus as in claim 1, wherein the plurality of ring members are supplied singly or as part of a consumable process kit.

31. A plasma apparatus, comprising:
a vacuum chamber provided with an exhaust port; and
a chuck assembly disposed inside the vacuum chamber, the chuck assembly being constructed and arranged to hold a substrate; and
a plasma confinement and pressure control apparatus disposed proximate the substrate, the plasma confinement and pressure control apparatus comprising:
a plurality of ring members disposed adjacent to each other in a superposed fashion;
a plurality of lift assemblies disposed along a circumference of the plurality of ring members, the plurality of lift assemblies arranged to support the plurality of ring members; and
at least one lift mechanism connected to each of the plurality of lift assemblies,
wherein the at least one lift mechanism is configured to translate at least one of the plurality of ring members relative to a reference plane and to tilt the at least one of the plurality of the ring members relative to the reference plane.

32. A plasma apparatus as in claim 31, wherein the reference plane is at least one of a fixed reference plane and a plane defined by another of the plurality of ring members.

33. A plasma apparatus as in claim 32, wherein the plurality of lift assemblies are mounted to the chuck assembly and the reference plane is a plane defined by a surface of the chuck assembly on which the substrate is disposed.

34. A plasma apparatus as in claim 32, further comprising an electrode assembly constructed and arranged adjacent to the chuck assembly, the electrode assembly and the chuck assembly defining a plasma region therebetween, wherein the plurality of lift assemblies are mounted to the electrode assembly and the reference plane is a plane defined by a surface of the electrode assembly.

35. A plasma apparatus as in claim 31, wherein the plurality of lift assemblies are mounted to a wall of the vacuum chamber.

36. A plasma apparatus as in claim 31, wherein the plurality of ring members have a circular shape, a polygonal shape, an elliptical shape or a combination thereof.

37. A plasma apparatus as in claim 31, wherein the plurality of lift assemblies comprise a plurality of lift pins, each lift pin is connected at one end to one of the plurality of ring members and connected at another end to the at least one lift mechanism.

38. A plasma apparatus as in claim 37, wherein the at least one lift mechanism is configured to extend or retract independently the plurality of lift pins to lift, lower or tilt at least one of the ring members.

39. A plasma apparatus as in claim 31, wherein the at least one lift mechanism is adapted to control a spacing between at least two of the plurality of ring members.

40. A plasma apparatus as in claim 39, wherein the spacing between at least two of the plurality of ring members is controllable to adjust a pressure inside a volume delimited by the plurality of ring members.

41. A plasma apparatus as in claim 31, wherein the at least one lift mechanism is adapted to control a tilting of at least one of the plurality of ring members relative to another of the plurality of ring members.

42. A plasma apparatus as in claim 41, wherein the tilting between at least two of the plurality of ring members is controllable to adjust a pressure inside a plasma volume delimited by the plurality of ring members.

43. A plasma apparatus as in claim 37, wherein the plurality of lift assemblies further comprise a plurality of bellows, each bellows is terminated at one end with a first ring element connected to the lift pin and terminated at an another end with a second ring element having a hole through which the lift pin slides.

44. A plasma apparatus as in claim 43, wherein the bellows is configured to isolate pressure environments inside the vacuum chamber and outside the vacuum chamber.

45. A plasma apparatus as in claim 31, wherein the at least one lift mechanism includes a gear driven lift mechanism, a belt driven lift mechanism, a pneumatic lift mechanism, a hydraulic lift mechanism, a piezo-electric lift mechanism or a stepper motor lift mechanism.

46. A plasma apparatus as in claim 31, further comprising a gas supply system in communication with the plasma vacuum chamber, wherein the plurality of lift assemblies comprise a plurality of lift pins, at least one of the lift pins having a canal configured to transfer gas from the gas supply system into a gas plenum within at least one of the plurality of ring members.

47. A plasma apparatus as in claim 46, wherein the gas includes at least one of hydrogen-bromide, octafluorocyclobutane, fluorocarbon compounds, silane, tungsten-tetrachloride, and titanium-tetrachloride.

48. A plasma apparatus as in claim 46, wherein the at least one of the plurality of ring members has a plurality of holes through which gas is injected into a volume defined by the plurality of ring members.

49. A plasma apparatus as in claim 31, further comprising a plasma-monitoring device disposed within a cavity in at least one of the plurality of ring members, wherein the plurality of lift assemblies comprise a plurality of lift pins connected to the plurality of ring members and at least one of the plurality of lift pins has a canal configured to electrically access the plasma-monitoring device disposed within the cavity in the at least one of the plurality of ring members.

50. A plasma apparatus as in claim 48, wherein the plasma-monitoring device includes of a temperature measuring device, a radio-frequency measuring device, a DC voltage measuring device, an electrical current measuring device or a combination thereof.

51. A plasma confinement and pressure control apparatus as in claim 49, wherein the plasma-monitoring device is configured to measure a parameter of a plasma in a volume enclosed by the plurality of ring members.

52. A plasma apparatus as in claim 31, further comprising a magnetic component disposed within a cavity in at least one of the plurality of ring members.

53. A plasma apparatus as in claim 52, wherein the magnetic component includes any one of a permanent magnet, a solenoid-type magnet or a combination thereof.

54. A plasma apparatus as in claim 52, wherein the magnetic component is configured to generate a magnetic field to confine a plasma in a volume enclosed by the plurality of ring members.

55. A plasma confinement and pressure control apparatus as in claim 31, wherein at least one of the ring members is electrically polarized by applying an electrical potential.

56. A plasma apparatus as in claim 54, wherein the plurality of lift assemblies comprise a plurality of lift pins connected to the plurality of ring members and at least one of the plurality of lift pins has a canal therethrough configured to introduce an electrical connection to at least one of the ring members.

57. A plasma apparatus as in claim 56, wherein at least two adjacent ring members are electrically isolated from each other.

58. A plasma apparatus as in claim 57, wherein the at least two adjacent ring members are held at different electrical potentials.

59. A plasma apparatus as in claim 31, wherein the vacuum chamber comprises sidewalls and an exhaust port to which is connected a vacuum pump configured to evacuate gases from the vacuum chamber.

60. A plasma apparatus as in claim 31, wherein the plurality of ring members are manufactured from at least one of metallic materials, ceramic materials, or quartz.

61. A plasma apparatus as in claim 31, wherein the plurality of ring members are coated with various materials depending on plasma process requirements.

62. A plasma apparatus as in claim 31, wherein the plurality of ring members are supplied singly or as part of a consumable process kit.

63. A plasma apparatus as in claim 31, wherein the at least one lift mechanism in said plasma confinement and pressure control apparatus has a plurality of independent actuation systems connected to the plurality of lift assemblies.

64. A method of controlling pressure in a vicinity of a substrate disposed on a chuck assembly in a plasma apparatus with an apparatus comprising a plurality of ring members disposed adjacent to each other and a plurality of lift assemblies disposed along a circumference of the plurality of ring members to support the plurality of ring members, the method comprising:
controlling a spacing between at least two of the plurality of ring members; and
adjusting a pressure inside a volume delimited by the plurality of ring members across the substrate by controlling a tilting of at least one of the plurality of ring members relative to another one of the ring members or to a reference plane.

65. A method of controlling a plasma in a vicinity of a substrate disposed on a chuck assembly in a plasma apparatus with a apparatus comprising a plurality of ring members disposed adjacent to each other and a plurality of lift assemblies disposed along a circumference of the plurality of ring members to support the plurality of ring members, the method comprising:
applying at least one of an electrical field and a magnetic field to a plasma volume delimited by the plurality of the ring members by connecting at least one of the plurality of ring members to an electrical potential or by disposing magnetic components in a periphery of at least one of the ring members; and
altering characteristics of the plasma in the vicinity of the substrate.
